(19) United States
(12) Patent Application Publication
(10) Pub. No.: US 2011/0031952 A1
(43) Pub. Date: Feb. 10, 2011

(54) SEMICONDUCTOR APPARATUS AND POWER SOURCE CIRCUIT

(75) Inventor: Kazutoshi NAKAMURA, Kanagawa-ken (JP)

Correspondence Address: PATTERSON & SHERIDAN, L.L.P., 3040 POST OAK BOULEVARD, SUITE 1500, HOUSTON, TX, 77056, US

(73) Assignee: KABUSHIKI KAISHA TOSHIBA, Tokyo (JP)

(21) Appl. No.: 12/851,396

(22) Filed: Aug. 5, 2010

(30) Foreign Application Priority Data
Aug. 5, 2009 (JP) 2009-182286

(51) Int. Cl. G05F 1/10; H01L 27/088

(52) U.S. Cl. 323/311; 257/392; 257/E27.061

(57) ABSTRACT

According to one embodiment, a semiconductor apparatus includes a substrate, a semiconductor layer of a first conductivity type, a first semiconductor region of a second conductivity type, a first main electrode, a second semiconductor layer of the second conductivity type, a third semiconductor layer of the first conductivity type, a second main electrode, a gate insulating film, and a gate electrode. An electron injected from the first semiconductor region into the semiconductor layer is recombined with an electron hole injected from the third semiconductor region into the semiconductor layer in a state of a body diode is biased in a forward direction. The body diode includes the semiconductor layer, the first semiconductor region, and the third semiconductor region.

### CROSS-REFERENCE TO RELATED APPLICATION

This application is based upon and claims the benefit of priority from the prior Japanese Patent Application No. 2009-182286, filed on Aug. 5, 2009; the entire contents of which are incorporated herein by reference.

### FIELD

Embodiments described herein relate generally to a semiconductor apparatus and a power source circuit.

### BACKGROUND

A voltage step-down DC-DC converter includes a high-side switching device and a low-side switching device connected in series between an input voltage line and a reference potential. A connection node between the high-side switching device and the low-side switching device is connected to an inductive load. The inductive load is connected to an output line. A voltage stepped-down from the input voltage is output to the output line by alternately switching the high-side switching device and the low-side switching device ON and OFF. At this time, to prevent the high-side switching device and the low-side switching device from being ON simultaneously, an interval (a dead time), which is an interval when both the high-side switching device and the low-side switching device are OFF, is provided between the ON interval of the high-side switching device and the ON interval of the low-side switching device.

A recovery current flows in the inductive load when the high-side switching device is switched from ON to OFF. At this time, a drain potential of the low-side switching device is lower than a grounding potential. During the dead time interval, a body diode existing between the drain and source of the low-side switching device is biased in the forward direction.

When the body diode is biased in the forward direction, electrons are injected from the cathode into a substrate. The electrons injected into the substrate may cause discrepancies such as misoperations of other circuits formed on the substrate.

Also, the electrons injected into the substrate may flow into diffusion layers connected to the input voltage and nodes having potentials higher than the grounding potential; and such current is lost. Accordingly, the number of dead times per unit time increases as the switching frequency of the high-side switching device increases, leading to a lower conversion efficiency.

Further, a known structure includes an N⁺-type buried layer in the substrate to prevent the injection of electrons into the substrate. However, epitaxial growth is necessary to form an N⁺-type buried layer having a high impurity concentration; and costs are higher than those of processes forming general MOS transistors without buried layers.

### BRIEF DESCRIPTION OF THE DRAWINGS

FIG. 1 is a circuit diagram of a power source circuit according to a first embodiment;

FIG. 2 is a cross-sectional diagram of a semiconductor apparatus according to an embodiment;

FIG. 3 is a diagram of a current characteristic of a low-side switching device illustrated in FIG. 1;

FIG. 4 is a circuit diagram of a power source circuit according to a second embodiment;

FIG. 5 is a diagram of a current characteristic of a low-side switching device illustrated in FIG. 4;

FIG. 6 is a cross-sectional diagram of another structure of the semiconductor apparatus according to the embodiment;

FIG. 7 is a cross-sectional diagram of yet another structure of the semiconductor apparatus according to the embodiment;

FIG. 8 is a cross-sectional diagram of yet another structure of the semiconductor apparatus according to the embodiment;

FIG. 9 is a cross-sectional diagram of yet another structure of the semiconductor apparatus according to the embodiment; and

FIG. 10 is a pattern diagram of a planar layout of the main components of the semiconductor apparatus having the structure illustrated in FIG. 6.

### DETAILED DESCRIPTION

According to one embodiment, a semiconductor apparatus includes a substrate, a semiconductor layer of a first conductivity type, a first semiconductor region of a second conductivity type, a first main electrode, a second semiconductor layer of the second conductivity type, a third semiconductor layer of the first conductivity type, a second main electrode, a gate insulating film, and a gate electrode. The semiconductor layer is provided in a surface side portion of the substrate. The first semiconductor region is provided in a surface side of the semiconductor layer. The first main electrode is connected to an inductive load and the first semiconductor region. The second semiconductor region is provided in the surface side of the semiconductor layer apart from the first semiconductor region. The third semiconductor region is provided in the surface side of the semiconductor layer apart from the first semiconductor region. The second main electrode is connected to a reference potential, the third semiconductor region, and the second semiconductor region. The gate insulating film is provided above the surface of the semiconductor layer between the first semiconductor region and the second semiconductor region. The gate electrode is provided above the gate insulating film. An electron injected from the first semiconductor region into the semiconductor layer is recombined with an electron hole injected from the third semiconductor region into the semiconductor layer. The electron is recombined with the electron hole in a state of a body diode is biased in a forward direction. The body diode includes the semiconductor layer, the first semiconductor region, and the third semiconductor region.

Embodiments will now be described with reference to the drawings.

### First Embodiment

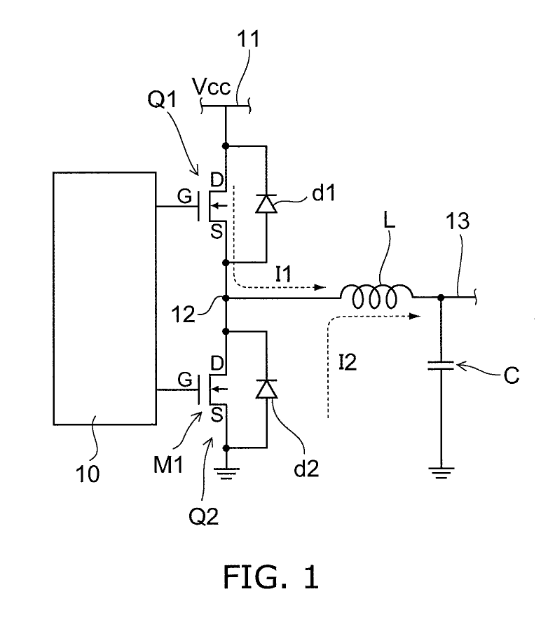

FIG. 1 is a circuit diagram of a power source circuit according to a first embodiment. In this embodiment, a voltage step-down DC-DC converter is illustrated as the power source circuit.

The DC-DC converter includes a high-side switching device Q1 and a low-side switching device Q2 connected in series between an input voltage line 11 and a ground, i.e., a reference potential. The high-side switching device Q1 and the low-side switching device Q2 alternately switch ON and OFF. Therefore, a voltage lower than an input voltage Vcc is output to an output line 13.

The high-side switching device Q1 and the low-side switching device Q2 are, for example, N-channel MOSFETs (Metal-Oxide-Semiconductor Field Effect Transistors).

A drain of the high-side switching device Q1 is connected to the input voltage line 11. A source of the high-side switching device Q1 is connected to a drain of the low-side switching device Q2. A source of the low-side switching device Q2 is connected to the ground.

A diode d1 connected between the drain and source of the high-side switching device Q1 represents a body diode (a built-in body diode) of the high-side switching device Q1. A diode d2 connected between the drain and source of the low-side switching device Q2 represents a body diode of the low-side switching device Q2.

A connection node 12 between the high-side switching device Q1 and the low-side switching device Q2 is connected to one end of an inductor L, i.e., an inductive load. The other end of the inductor L is connected to an output line 13. A smoothing capacitor C is connected between the output line 13 and the ground to prevent the output voltage from fluctuating greatly in a short period of time.

Each of the gates of the high-side switching device Q1 and the low-side switching device Q2 is connected to a control circuit 10. The control circuit 10 supplies gate control signals substantially in inverted phase to the gate of the high-side switching device Q1 and the gate of the low-side switching device Q2. Thereby, the ON/OFF of the high-side switching device Q1 and the low-side switching device Q2 is controlled.

In the case where both the high-side switching device Q1 and the low-side switching device Q2 are simultaneously switched ON, a shoot-through current flows from the input voltage line 11 to the ground via both switching devices Q1 and Q2. An interval (a dead time), in which both switching devices Q1 and Q2 are OFF, is set from when the high-side switching device Q1 is turned OFF until the low-side switching device Q2 is turned ON. And the interval, in which both switching devices Q1 and Q2 are OFF, is set from when the low-side switching device Q2 is turned OFF until the high-side switching device Q1 is turned ON. Therefore, the shoot-through current does not flow from the input voltage line 11 to the ground via both switching devices Q1 and Q2.

When the high-side switching device Q1 is ON and the low-side switching device Q2 is OFF, a current I1 flows from the input voltage line 11 to the output line 13 via the high-side switching device Q1 and the inductor L. At this time, an inductor current increases and energy is stored in the inductor L.

When the high-side switching device Q1 is switched OFF and the low-side switching device Q2 is switched ON, a recovery current I2 flows from the ground to the output line 13 via the low-side switching device Q2 and the inductor L by an electromotive force due to the energy stored in the inductor L. After the high-side switching device Q1 is switched OFF and during the dead time until the low-side switching device Q2 is switched ON, the recovery current I2 flows via the body diode d2 of the low-side switching device Q2.

Of the components illustrated in FIG. 1, the high-side switching device Q1, the low-side switching device Q2, and the control circuit 10 are semiconductor integrated circuits formed on the same substrate. In other words, the high-side switching device Q1, the low-side switching device Q2, and the control circuit 10 are formed as a power source IC integrated in one chip. The inductor L and the capacitor C are connected to the power source IC as external parts.

Alternatively, only the high-side switching device Q1 and the low-side switching device Q2 may be in one chip, only the high-side switching device Q1 and the control circuit 10 may be in one chip, or only the low-side switching device Q2 and the control circuit 10 may be in one chip. Although the high-side switching device Q1 is an N-channel MOSFET in the description hereinabove, a P-channel MOSFET also may be used.

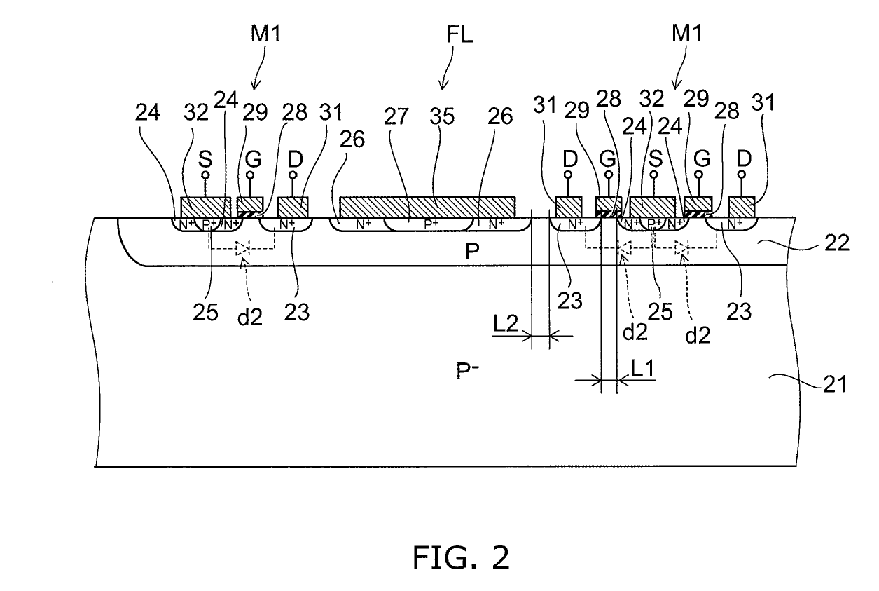

The structure of the low-side switching device Q2 will now be described referring to FIG. 2. Although the semiconductor material is, for example, silicon, in the specific examples hereinbelow, the semiconductor material is not limited to silicon. Other semiconductor materials may be used. Although the first conductivity type is a P-type and the second conductivity type is an N-type in the description, the first conductivity type may be the N-type and the second conductivity type may be the P-type.

The low-side switching device Q2 has a MOS (Metal-Oxide-Semiconductor) structure or a MIS (Metal-Insulator-Semiconductor) structure. Such structures are formed on a P⁻-type substrate 21. A P-type well layer 22 is formed in a surface side portion of the substrate 21.

An N⁺-type drain region 23 is selectively formed as a first semiconductor region in the surface side of the P-type well layer 22. An N⁺-type N⁺-type source region 24 is selectively formed as a second semiconductor region in the surface side of the P-type well layer 22. A P⁺-type P⁺-type contact region 25 is selectively formed as a third semiconductor region in the surface side of the P-type well layer 22. An N⁺-type semiconductor region 26 is selectively formed as a fourth semiconductor region in the surface side of the P-type well layer 22. A P⁺-type semiconductor region 27 is selectively formed as a fifth semiconductor region in the surface side of the P-type well layer 22.

The drain region 23 and the N⁺-type source region 24 are provided apart from each other. A gate insulating film 28 is provided on the surface of the P-type well layer 22 between the drain region 23 and the N⁺-type source region 24. A gate electrode 29 is provided on the gate insulating film 28. The gate electrode 29 is connected to the control circuit 10 illustrated in FIG. 1.

A drain electrode 31 is provided on the surface of the drain region 23 as a first main electrode. The drain region 23 is electrically connected to the drain electrode 31. The drain electrode 31 is connected to the connection node 12 and the inductor L illustrated in FIG. 1.

The N⁺-type source region 24 and the P⁺-type contact region 25 are in contact. A source electrode 32 is provided on the surface of the N⁺-type source region 24 and the P⁺-type contact region 25 as a second main electrode. The N⁺-type source region 24 and the P⁺-type contact region 25 are electrically connected to the source electrode 32. The source electrode 32 is connected to the ground. The potential of the source electrode 32 is provided to the P-type well layer 22 via the P⁺-type contact region 25.

The N⁺-type semiconductor region 26 and the P⁺-type semiconductor region 27 are provided apart from the drain region 23 on the side opposite to the N⁺-type source region 24. The N⁺-type semiconductor region 26 is provided between the drain region 23 and the P⁺-type semiconductor region 27 and is proximal to the drain region 23. Although the N⁺-type semiconductor region 26 and the P⁺-type semiconductor region 27 are in contact in FIG. 2, the N⁺-type semiconductor region 26 and the P⁺-type semiconductor region 27 may not contact each other.

A floating electrode 35 is provided on the surface of the N⁺-type semiconductor region 26 and the P⁺-type semiconductor region 27. The floating electrode 35 is not directly connected to the gate electrode 29, the source electrode 32, and the drain electrode 31. The N⁺-type semiconductor region 26 and the P⁺-type semiconductor region 27 are electrically connected to the floating electrode 35. In other words, the N⁺-type semiconductor region 26 and the P⁺-type semiconductor region 27 are electrically connected via the floating electrode 35. A floating structure portion FL includes the N⁺-type semiconductor region 26, the P⁺-type semiconductor region 27, and the floating electrode 35. The floating electrode 35 is electrically connectable to the source electrode 32 through the diffusion layers of the P⁺-type semiconductor region 27, the P-type well layer 22, and the P⁺-type contact region 25. The potential of the floating electrode 35 is substantially the same as the potential of the source electrode 32 when a current is not flowing between the floating electrode 35 and the source electrode 32.

A relationship L2≧L1 holds, where L1 is the distance between the N⁺-type source region 24 and the drain region 23 and L2 is the distance between the N⁺-type semiconductor region 26 and the drain region 23. A punch-through voltage between the drain electrode 31 and the source electrode 32 is determined by the distance between the N⁺-type source region 24 and the drain region 23. The P-type well layer 22 between the N⁺-type source region 24 and the drain region 23 is more easily depleted in the case where there is no gate electrode 29.

The drain region 23, the N⁺-type source region 24, and the N⁺-type semiconductor region 26 are simultaneously formed by selective implantation of an N-type impurity. The P⁺-type contact region 25 and the P⁺-type semiconductor region 27 are formed simultaneously by selective implantation of a P-type impurity.

The drain region 23, the N⁺-type source region 24, the P⁺-type contact region 25, the gate insulating film 28, and the gate electrode 29 form a MOS transistor M1.

The body diode d2 includes the P⁺-type contact region 25, the P-type well layer 22, and the drain region 23. In the body diode d2, the source electrode 32 functions as an anode electrode and the drain electrode 31 functions as a cathode electrode.

In the case where a voltage not less than the threshold voltage of the gate electrode 29 of the MOS transistor M1 of the low-side switching device Q2 is applied, an N-type inversion layer (a channel) is formed in the surface side of the P-type well layer 22 below the gate electrode 29; and the MOS transistor M1 is switched ON. When the high-side switching device Q1 is OFF and the MOS transistor M1 of the low-side switching device Q2 is ON, a recovery current I2 flows via the source electrode 32, the N⁺-type source region 24, the channel, the drain region 23, and the drain electrode 31. At this time, the drain potential of the low-side switching device Q2 is a negative potential lower than the source potential (0 V).

When both the high-side switching device Q1 and the MOS transistor M1 of the low-side switching device Q2 are OFF, the recovery current I2 flows via the body diode d2 of the low-side switching device Q2. In other words, electrons are injected from the drain region 23 having the negative potential into the P-type well layer 22; and electron holes are injected from the P⁺-type contact region 25 having the source potential (0 V) into the P-type well layer 22. A portion of the electrons injected into the P-type well layer 22 flows into the source electrode 32 via the P⁺-type contact region 25. The electron holes injected into the P-type well layer 22 flow into the drain electrode 31 having the negative potential via the drain region 23.

Although no bias is applied to the N⁺-type semiconductor region 26, a built-in potential occurs in the PN junction between the N⁺-type semiconductor region 26 and the P-type well layer 22. Therefore, the electrons injected into the P-type well layer 22 flow into the N⁺-type semiconductor region 26. Because the N⁺-type semiconductor region 26 is connected to neither the source electrode 32 nor the drain electrode 31, the N⁺-type semiconductor region 26 is biased with a negative potential by the injection of the electrons. The P⁺-type semiconductor region 27 is biased with a negative potential via the floating electrode 35; and the P-type well layer 22 around the P⁺-type semiconductor region 27 is negatively biased. Thus, the negatively-biased P-type well layer 22 forms a barrier to the electrons injected from the drain region 23; and the injection of the electrons into the substrate 21 can be suppressed.

The electrons flowing in the N⁺-type semiconductor region 26 provide the N⁺-type semiconductor region 26 with a negative potential. The P⁺-type semiconductor region 27 is electrically connected to the N⁺-type semiconductor region 26 via the floating electrode 35. Therefore, the potential of the P⁺-type semiconductor region 27 becomes negative. Thereby, electron holes in the P-type well layer 22 flow into the P⁺-type semiconductor region 27. Accordingly, the electrons flowing into the N⁺-type semiconductor region 26 and the electron holes flowing into the P⁺-type semiconductor region 27 are recombined by the floating electrode 35; and the body diode d2 does not have a forward direction current. Accordingly, the current driving capability of the body diode d2 decreases.

As a result, the amount of electrons in the P-type well layer 22 decreases. The decrease of the amount of electrons in the P-type well layer 22 reduces the amount of electrons injected into the substrate 21. Therefore, the flow of electrons into high potential portions of the control circuit 10 can be suppressed. The control circuit 10 is formed on the same substrate 21. Therefore, misoperations of the control circuit 10 are prevented.

The amount of electrons stored in the substrate 21 can be reduced. Therefore, when the high-side switching device Q1 is switched ON, the electrons flowing to the input voltage line 11 via the high-side switching device Q1 can be reduced. The electrons flowing to the input voltage line 11 via the high-side switching device Q1 is not supplied to the output line 13. That is, the flow of the electrons is ineffective current. As a result, a decrease of the conversion efficiency (output power/input power) is prevented.

When a voltage not less than the threshold voltage of the gate electrode 29 is applied and the MOS transistor M1 is switched ON, substantially all of the recovery current I2 flows in the low-resistance channel of the MOS transistor M1. In other words, electrons flow in the P-type well layer 22 surface side. Therefore, substantially none of the electrons are injected into the substrate 21.

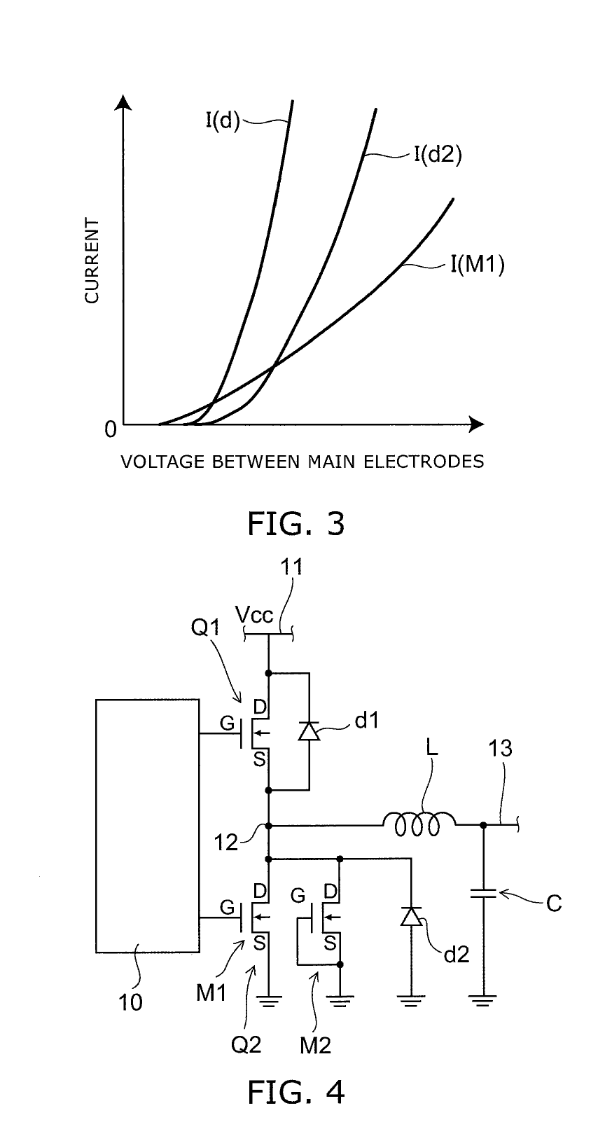

FIG. 3 illustrates a current characteristic I (M1) of the MOS transistor M1, a current characteristic I (d2) of the body diode d2 of the semiconductor apparatus of this embodiment including the floating structure portion FL, and a current characteristic I (d) of a body diode of a comparative example. The comparative example has a structure in which the floating structure portion FL is not provided.

In FIG. 3, the source-drain voltage of the MOS transistor M1, the anode-cathode voltage of the body diode d2, and the anode-cathode voltage of the body diode of the comparative example are plotted on the horizontal axis. The current flowing in the channel of the MOS transistor M1, the forward direction current of the body diode d2, and the forward direction current of the body diode of the comparative example are plotted on the vertical axis.

In this embodiment, the floating structure portion FL is provided to promote the recombination of the electrons and the electron holes in the P-type well layer 22 in the state in which the body diode d2 is biased in the forward direction. Therefore, for the same anode-cathode voltage, the current I (d2) of the body diode d2 is lower than the current I (d) of the body diode of the comparative example in which the floating structure portion FL is not provided. In other words, by providing the floating structure portion FL, the current driving capability of the body diode d2 is reduced.

In the case where a high-level signal, which switches the MOS transistor M1 ON, is not supplied from the control circuit 10 to the gate electrode 29, the gate potential of the MOS transistor M1 is 0 V. At this time, when the potential of the connection node 12 becomes negative, the gate potential (0 V) becomes higher than the negative potential of the connection node 12. The drain potential of the MOS transistor M1 is the same as the potential of the connection node 12. In the case where the potential of the connection node 12 is −V_{D}, the source potential and the gate potential of the MOS transistor M1 are V_{D} higher than the drain potential. Accordingly, when V_{D} is higher than the threshold voltage of the MOS transistor M1, the MOS transistor M1 is switched ON.

In this embodiment, the current driving capability of the body diode d2 is reduced. Therefore, the driving current region of the MOS transistor M1 increases. In the case where current flows through the channel of the MOS transistor M1, substantially no current flows in the substrate 21.

According to this embodiment as described above, in the recovery current mode, current flowing in the substrate 21 can be suppressed by the floating structure portion FL provided on the P-type well layer 22 surface side promoting the recombination of the electrons and the electron holes. As a result, the current flowing in other circuits of the control circuit 10 and the like formed on the substrate 21 is suppressed; and misoperations of such circuits are prevented. To realize such a function in this embodiment, it is unnecessary to epitaxially grow an N⁺-type buried layer having a high impurity concentration in the substrate 21. Therefore, applications are possible using processes forming general MOS transistors; and cost increases are avoided.

### Second Embodiment

FIG. 4 illustrates the DC-DC converter according to a second embodiment. Components similar to those of FIG. 1 are marked with like reference numerals.

In this embodiment, a MOS transistor M2 is connected between the connection node 12 and the ground in parallel with the MOS transistor M1. A drain of the MOS transistor M2 is connected to the connection node 12. A gate and a source of the MOS transistor M2 are connected to each other. The gate and the source of the MOS transistor M2 are connected to the ground. In other words, the MOS transistor M2 has a diode-like connection between the connection node 12 and the ground. The MOS transistor M2 is formed on the substrate 21 on which the MOS transistor M1 is formed.

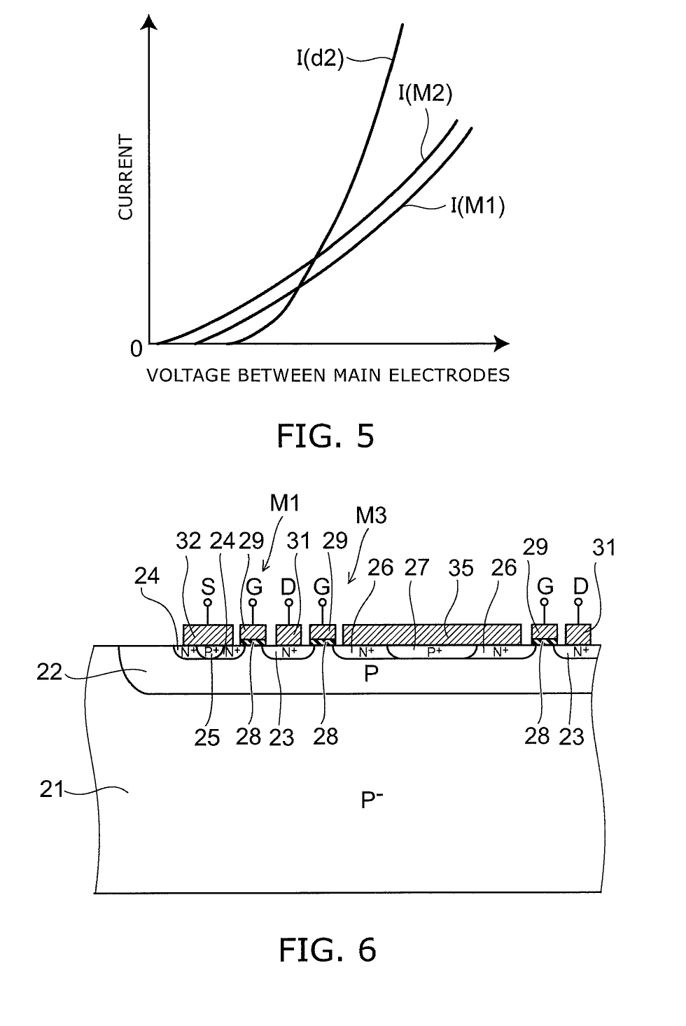

FIG. 5 illustrates the current characteristic I (M1) of the MOS transistor M1, the current characteristic I (M2) of the MOS transistor M2, and the current characteristic I (d2) of the body diode d2.

In FIG. 5, the source-drain voltage of the MOS transistor M1, the source-drain voltage of the MOS transistor M2, and the anode-cathode voltage of the body diode d2 are plotted on the horizontal axis. The current flowing in the channel of the MOS transistor M1, the current flowing in the channel of the MOS transistor M2, and the forward direction current of the body diode d2 are plotted on the vertical axis.

A threshold voltage of the MOS transistor M2 is set lower than a threshold voltage of the MOS transistor M1. The MOS transistors M1 and M2 operate in a voltage region lower than the forward direction voltage of the body diode d2.

The MOS transistor M2 operates in a voltage region lower than that of the MOS transistor M1 by setting the threshold voltage of the MOS transistor M2 lower than the threshold voltage of the MOS transistor M1. Therefore, the region where the current flows through the MOS channel can be wider. And the injection of electrons into the substrate 21 can be suppressed over a greater current range.

In the case where a voltage change of the connection node 12 from a low potential to a high potential is great, a displacement current due to the gate-drain capacitance of the MOS transistor M2 flows into the gate electrode. In such a case, the displacement current flows in the parasitic gate resistance existing in the gate electrode and the driver resistance which drives the gate of the MOS transistor M2. In other words, the displacement current flows between the gate and source. And a positive potential with respect to the source potential occurs in the gate electrode. In the case where this positive potential exceeds a threshold voltage, a current flows between the drain and the source of the MOS transistor M2. The current flowing between the drain and the source is an ineffective current and leads to a lower conversion efficiency (output power/input power). Accordingly, the driver resistance which drives the gate can be eliminated by connecting the gate and the source of the MOS transistor M2. And the positive potential occurring due to the displacement current can be controlled.

However, in the case where the gate resistance and the driver resistance are sufficiently low, the positive potential occurring due to the displacement current is low. Therefore, the gate of the MOS transistor M2 may not be connected to the source. In such a case, the gate of the MOS transistor M2 may be connected to the gate of the MOS transistor M1. Thus, the MOS transistor M2 also may be used as a switching device. Therefore, the ON resistance of the low-side MOS can be lower than that of the case where the gate of the MOS transistor M2 is connected to the source of the MOS transistor M2 for the conditions of a constant surface area.

FIG. 6 illustrates another specific example of the structure corresponding to FIG. 2. The components similar to those of FIG. 2 are marked with like reference numerals. In the structure of FIG. 6, the gate insulating film 28 and the gate electrode 29 are provided also above the surface of the P-type well layer 22 between the drain region 23 and the N⁺-type semiconductor region 26. That is, a MOS transistor M3 is provided. When a voltage not less than the threshold voltage is applied to the gate electrode 29, an N-type channel is formed also in the surface side of the P-type well layer 22 between the drain region 23 and the N⁺-type semiconductor region 26. Electrons flow between the drain electrode 31 and the source electrode 32 through the drain region 23, the channel formed directly below the gate electrode 29, the N⁺-type semiconductor region 26, the P⁺-type semiconductor region 27, the P-type well layer 22, and the P⁺-type contact region 25. The larger channel region reduces the ON resistance compared to that of the structure of FIG. 2 when the gate is switched ON.

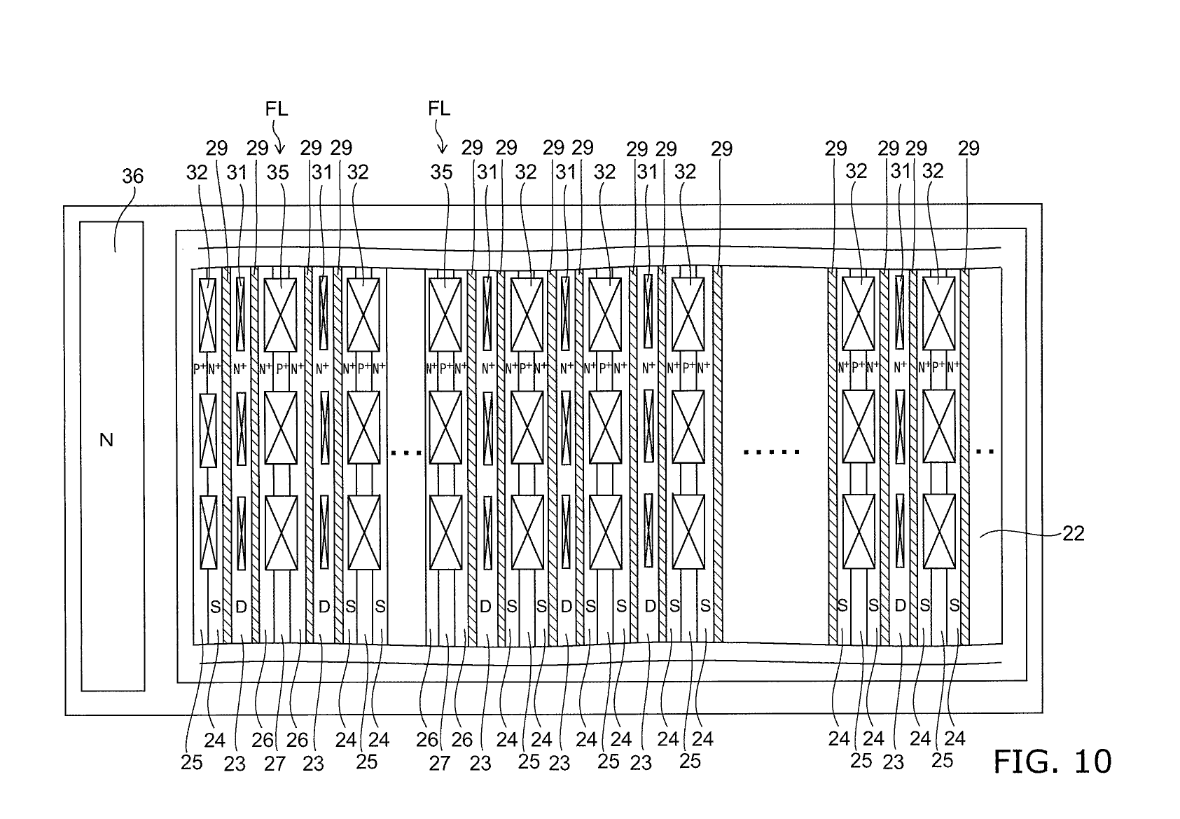

FIG. 10 is a planar layout of the main components of the semiconductor apparatus having the structure illustrated in FIG. 6. The components similar to those of FIG. 6 are marked with like reference numerals. An N-type diffusion layer 36 is connected to the input voltage around the low-side MOSs or a potential higher than the grounding potential. The N-type diffusion layer 36 attracts electrons injected into the substrate 21. Accordingly, more electrons are injected from the drains of the low-side MOSs adjacent to the N-type diffusion layer 36 than the drains positioned distal to the N-type diffusion layer 36.

Many of the electrons injected from the drains of the low-side MOSs positioned distal to the N-type diffusion layer 36 flow into the source electrode 32. Therefore, the floating structure portion FL is provided in the low-side MOSs adjacent to the N-type diffusion layer 36. The floating structure portion FL is not provided in the low-side MOSs positioned distal to the N-type diffusion layer 36. It is desirable for the region of the low-side MOSs having the floating structure portion FL is in a range up to 200 μm from the N-type diffusion layer 36. Thus, the increase of the ON resistance can be prevented by providing the floating structure portion FL.

An N-type channel is formed in the surface side of the P-type well layer 22 between the drain region 23 and the N⁺-type semiconductor region 26 in the MOS transistor M3. A current flows between the drain electrode 31 and the source electrode 32 through the drain region 23, the channel, the N⁺-type semiconductor region 26, the P⁺-type semiconductor region 27, the P-type well layer 22, and the P⁺-type contact region 25. In other words, the current flows via the P-type well layer 22. Therefore, the MOS transistor M3 has an ON resistance higher than that of the MOS transistor M1 due to the resistance of the P-type well layer 22. In the MOS transistor M1, the current flows directly from the drain electrode 31 to the source electrode 32 through the device surface side.

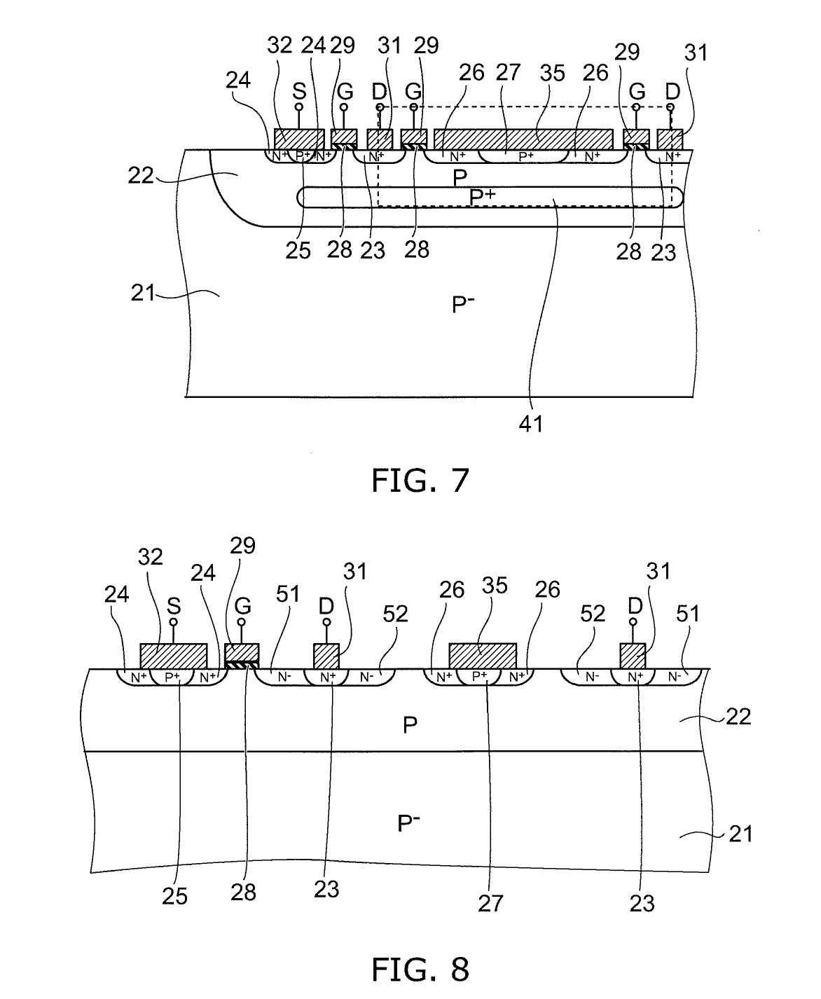

Therefore, a P⁺-type layer 41 is provided at a position in the P-type well layer 22 deeper than the diffusion layer on the surface side in the structure illustrated in FIG. 7. The P⁺-type layer 41 can be formed by high-acceleration implantation of the P-type impurity ions. The P⁺-type layer 41 reduces the diffusion resistance of the P-type well layer 22. Therefore, it is possible to reduce the ON resistance of the MOS transistor M3. The current driving capability of the MOS structure portion enclosed with the broken line in FIG. 7 can be increased.

FIG. 8 is another specific example of the semiconductor apparatus according to this embodiment.

This structure differs from that of FIG. 2 in that an N⁻-type drift region 51 is provided in the surface side of the P-type well layer 22 between the drain region 23 and the gate electrode 29. Also, an N⁻-type drift region 52 is provided in the surface side of the P-type well layer 22 between the N⁺-type semiconductor region 26 and the drain region 23. The structure of FIG. 8 can have a higher drain-source breakdown voltage than that of the structure of FIG. 2.

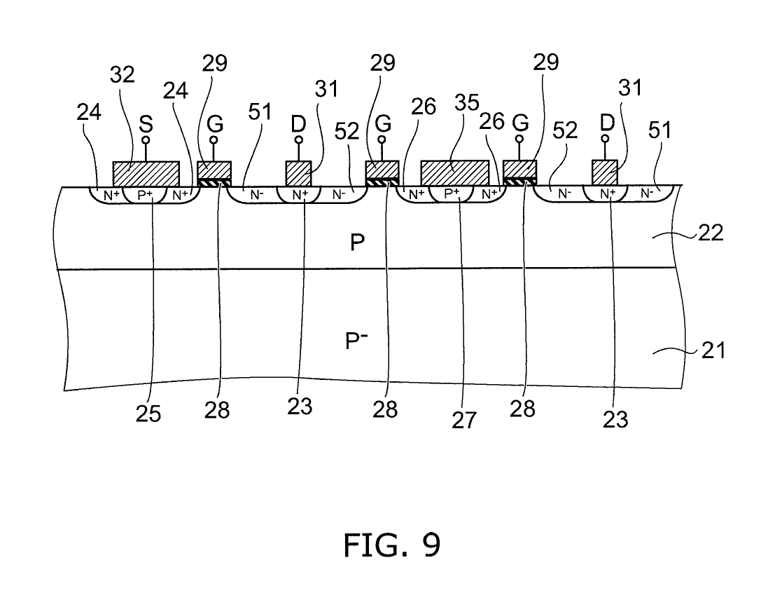

In the structure of FIG. 8, the gate insulating film 28 and the gate electrode 29 similar to those of the structure of FIG. 6 may be provided on the surface side of the P-type well layer 22 between the drift region 52 and the N⁺-type semiconductor region 26. Such a structure is illustrated in FIG. 9.

When a voltage not less than the threshold voltage is applied to the gate electrode 29, an N-type channel is formed also in the surface side of the P-type well layer 22 between the drift region 52 and the N⁺-type semiconductor region 26.

Electrons can flow between the drain electrode 31 and the source electrode 32 through the drain region 23, the channel, the N⁺-type semiconductor region 26, the P⁺-type semiconductor region 27, the P-type well layer 22, and the P⁺-type contact region 25. The larger channel region reduces the ON resistance compared to that of the structure of FIG. 8 when the gate is ON.

While certain embodiments have been described, these embodiments have been presented by way of example only, and are not intended to limit the scope of the inventions. Indeed, the novel apparatuses and circuits described herein may be embodied in a variety of other forms; furthermore, various omissions, substitutions and changes in the form of the apparatuses and circuits described herein may be made without departing from the spirit of the inventions. The accompanying claims and their equivalents are intended to cover such forms or modification as would fall within the scope and spirit of the inventions.

1. A semiconductor apparatus, comprising:
a substrate;
a semiconductor layer of a first conductivity type provided in a surface side portion of the substrate;
a first semiconductor region of a second conductivity type provided in a surface side of the semiconductor layer;
a first main electrode connected to an inductive load and the first semiconductor region;
a second semiconductor region of the second conductivity type provided in the surface side of the semiconductor layer apart from the first semiconductor region;
a third semiconductor region of the first conductivity type provided in the surface side of the semiconductor layer apart from the first semiconductor region;
a second main electrode connected to a reference potential, the third semiconductor region, and the second semiconductor region;
a gate insulating film provided above the surface of the semiconductor layer between the first semiconductor region and the second semiconductor region; and
a gate electrode provided above the gate insulating film,
an electron injected from the first semiconductor region into the semiconductor layer being recombined with an electron hole injected from the third semiconductor region into the semiconductor layer in a state of a body diode being biased in a forward direction, the body diode including the semiconductor layer, the first semiconductor region, and the third semiconductor region.

2. The apparatus according to claim 1, further comprising a transistor connected between the inductive load and the reference potential in parallel with a low-side switching device including the first semiconductor region, the second semiconductor region, the third semiconductor region, the gate insulating film, and the gate electrode,
a threshold voltage of the transistor being lower than a threshold voltage of the low-side switching device.

3. The apparatus according to claim 2, wherein a source electrode of the transistor is connected to a gate electrode of the transistor.

4. The apparatus according to claim 1, further comprising a control circuit provided above the substrate to control the gate electrode.

5. The apparatus according to claim 1, further comprising a high-side switching device provided above the substrate and connected between an input voltage line, and a connection node of the first main electrode and the inductive load.

6. A semiconductor apparatus, comprising:
a substrate;
a semiconductor layer of a first conductivity type provided in a surface side portion of the substrate;
a first semiconductor region of a second conductivity type provided in a surface side of the semiconductor layer;
a first main electrode connected to an inductive load and the first semiconductor region;
a second semiconductor region of the second conductivity type provided in the surface side of the semiconductor layer apart from the first semiconductor region;
a third semiconductor region of the first conductivity type provided in the surface side of the semiconductor layer apart from the first semiconductor region;
a second main electrode connected to a reference potential, the third semiconductor region, and the second semiconductor region;
a gate insulating film provided above the surface of the semiconductor layer between the first semiconductor region and the second semiconductor region;
a gate electrode provided above the gate insulating film;
a fourth semiconductor region of the second conductivity type provided in the surface side of the semiconductor layer apart from the first semiconductor region, the second semiconductor region, and the third semiconductor region;
a fifth semiconductor region of the first conductivity type provided in the surface side of the semiconductor layer apart from the first semiconductor region, the second semiconductor region, and the third semiconductor region; and
a floating electrode connecting the fourth semiconductor region to the fifth semiconductor region.

7. The apparatus according to claim 6, wherein the fourth semiconductor region is provided between the first semiconductor region and the fifth semiconductor region.

8. The apparatus according to claim 6, wherein the gate insulating film is provided also above the surface of the semiconductor layer between the fourth semiconductor region and the first semiconductor region, the gate electrode is provided also on the gate insulating film between the fourth semiconductor region and the first semiconductor region.

9. The apparatus according to claim 8, further comprising a first conductivity type layer provided in the semiconductor layer, the first conductivity type layer having a first conductivity type impurity concentration higher than a first conductivity type impurity concentration of the semiconductor layer.

10. The apparatus according to claim 6, further comprising a transistor connected between the inductive load and the reference potential in parallel with a low-side switching device including the first semiconductor region, the second semiconductor region, the third semiconductor region, the gate insulating film, and the gate electrode,
a threshold voltage of the transistor being lower than a threshold voltage of the low-side switching device.

11. The apparatus according to claim 10, wherein a source electrode of the transistor is connected to a gate electrode of the transistor.

12. The apparatus according to claim 6, further comprising a control circuit provided on the substrate to control the gate electrode.

13. The apparatus according to claim 6, further comprising a high-side switching device provided on the substrate and connected between an input voltage line, and a connection node of the first main electrode and the inductive load.

14. A power source circuit, comprising:
a high-side switching device connected to an input voltage line;
a low-side switching device connected between the high-side switching device and a reference potential;
an inductive load connected between an output line, and a connection node of the high-side switching device and the low-side switching device; and
a capacitor connected between the output line and the reference potential,
the low-side switching device including:
a substrate;
a semiconductor layer of a first conductivity type provided in a surface side portion of the substrate;
a first semiconductor region of a second conductivity type provided in a surface side of the semiconductor layer,
a first main electrode connected to the inductive load and the first semiconductor region;
a second semiconductor region of the second conductivity type provided in the surface side of the semiconductor layer apart from the first semiconductor region;
a third semiconductor region of the first conductivity type provided in the surface side of the semiconductor layer apart from the first semiconductor region;
a second main electrode connected to a reference potential, the third semiconductor region, and the second semiconductor region;
a gate insulating film provided above the surface of the semiconductor layer between the first semiconductor region and the second semiconductor region; and
a gate electrode provided above the gate insulating film,
an electron injected from the first semiconductor region into the semiconductor layer recombining with an electron hole injected from the third semiconductor region into the semiconductor layer in a state of a body diode being biased in a forward direction, the body diode including the semiconductor layer, the first semiconductor region, and the third semiconductor region.

15. The circuit according to claim 14, comprising:
a fourth semiconductor region of the second conductivity type provided in the surface side of the semiconductor layer apart from the first semiconductor region, the second semiconductor region, and the third semiconductor region;
a fifth semiconductor region of the first conductivity type provided in the surface side of the semiconductor layer apart from the first semiconductor region, the second semiconductor region, and the third semiconductor region; and
a floating electrode connecting the fourth semiconductor region to the fifth semiconductor region,
the electron and the electron hole being recombined by the floating electrode.

16. The circuit according to claim 14, further comprising a transistor connected between the connection node and the reference potential in parallel with the low-side switching device,
a threshold voltage of the transistor being lower than a threshold voltage of the low-side switching device.
